(19) United States
(12) Patent Application Publication
(10) Pub. No.: US 2011/0215226 A1
(43) Pub. Date: Sep. 8, 2011

(54) PHOTOSENSITIVE STRUCTURE WITH CHARGE AMPLIFICATION

(76) Inventor: Dmitri Jerdev, South Pasadena, CA (US)

(21) Appl. No.: 12/716,566

(22) Filed: Mar. 3, 2010

(51) Int. Cl. H01L 31/102; H01L 31/18

(52) U.S. Cl. 250/214 A; 438/59; 257/290; 250/214 SW; 250/214 R; 257/E31.052

(57) ABSTRACT

Presented invention describes the approach for manufacturing of the pixels for solid state imaging devices possessing a photon detection efficiency superior to those currently available. Formation of a bipolar junction transistor (BJT) in close vicinity of the photodiode in such a way that accumulation area of the photodiode also represents its collector region allows for conversion of the photo carriers which cannot be accumulated in a regular 4T pixel, usually holes, into complimentary type carriers, usually electrons, that can be stored, read out and converted to electric signal. This transistor can be formed, for example, by creating a n+ region inside the surface p layer of the pinned photodiode. In the described structure the accumulation region is isolated from the surface and operation of the new pixel is otherwise similar to the 4T pixel operation. As a result, both main advantages of 4T pixel: low dark current and kTC noise cancellation are, therefore, preserved.

### FIELD OF THE INVENTION

The present invention relates to the field of semiconductor devices and, in particular, image sensors.

### BACKGROUND OF THE INVENTION

A CMOS image sensor includes a plurality of photosensitive pixel cells forming focal plane array and circuitry for their readout. Each cell includes a photosensor, for example, a photodiode which collects photo-generated charge in a doped region of the substrate called n-well. State of the art cell in modern CMOS image sensors consist of four transistor (4T) design which greatly reduced a number of “hot” pixels in the array as well as diminishes kTC noise that 3T design may experience.

In a CMOS image sensor pixel a typical (4T) cell performs the functions necessary for device operation: (1) charge collection; (2) charge transfer to a floating diffusion; (3) conversion of charge into electric signal; (4) output selection and amplification of the signal; (5) photodiode and a floating diffusion reset.

Exemplary CMOS imaging circuits, processing steps thereof, and detailed descriptions of the functions of various CMOS elements of an imaging circuit are described, for example, in U.S. Pat. No. 6,215,113; U.S. Pat. No. 6,021,172; and U.S. Pat. No. 5,904,493;

FIG. 1A and FIG. 1B show a conventional CMOS four-transistor (4T) pixel cell. Top-down view is depicted in FIG. 1A while cross-section view taken along line A-A is shown in FIG. 1B. In the FIG. 1A pixel cell is denoted as 101. It includes photodiode 105, transfer transistor 107, floating diffusion 106, reset transistor 108, source follower 109, and select transistor 110.

Photodiode 101 consist of burred n− accumulation region 103 where initial accumulation of photo-generated carriers occurs and surface p+ layer 102. Charge transfer from photodiode 105 into floating diffusion 106 occurs by means of transfer gate 107 which in its turn is connected to the source follower transistor 109 which amplifies the signal. Selection of a particular pixel in the array is done with a select transistor 110.

The photodiode 101 contains a burred n− layer 103 that is surrounded by p type regions and can be fully depleted. Surface p+ layer is called a “pinned” layer and determines a potential of the n− layer when fully depleted. It also isolates a burred accumulation region 103 from the surface thus reducing a dark current from the surface states and introduces the second shallow p-n junction that greatly improves sensitivity in the blue area of the spectrum.

The process of light registration by the photodiode 101 consist of photon absorption, in which an electron-hole pair is generated, and than a separation of that pair by the electric field existing in vicinity of the p-n junctions between the accumulation region 103 and the pinned layer 102 and the accumulation region 103 and the p doped substrate 104. This field transfers electrons into the accumulation region 102 where they are stored until transferred to the floating diffusion 106 by means of the transfer gate 107. Holes that were generated in the process of light adsorption are not stored and thus do not contribute to the pixel signal.

### BRIEF SUMMARY OF THE INVENTION

Presented exemplary embodiment of the invention describes the approach that allows manufacturing of the pixels for solid state imaging devices that possess photon detection efficiency superior to those currently available. The main idea of the approach is to form a bipolar junction transistor (BJT) in close vicinity of the photodiode in such a way that accumulation area of the photodiode also represents its collector region. This can be done, for instance, by forming n+ region inside the surface p layer of the pinned photodiode. The claimed extra efficiency comes from a conversion of usually unregistered hole current into electrons by the aforementioned BJT(s). This electron current can be stored in the photodiode accumulation region and therefore be converted into useful signal during pixel readout respectively increasing sensitivity of the pixel. Since in the described structure the accumulation region is isolated from the surface and operation of the new pixel is otherwise similar to the 4T pixel operation from the prior art [0008] both main advantages of 4T pixel: low dark current and kTC noise cancellation are preserved.

Exemplary implementation of the patented idea is shown in the FIG. 2a, FIG. 2b and FIG. 2c. The BJT is produced by forming n+ region 111 in the top p layer 102 of the pixel 101. This region 111 represents an emitter of the BJT, photodiode accumulation region 103 represents its collector region and the p region 112 separating regions 111 and 103 represents the base region of the BJT. Therefore the new pixel is a combination of two types of devices, a pinned photodiode and a BJT(or BJTs) if several are formed). If n+ region area 111 is made larger than a photodiode active area 102 than the pinned photodiode is eliminated and the whole pixel becomes a BJT with a burred collector region where electrons are collected and stored.

### BRIEF DESCRIPTION OF THE DRAWINGS

The foregoing and other aspects of the invention will be better understood from the following detailed description of the invention, which is provided in connection with the accompanying drawings, in which:

FIG. 1A is a top-down view of a conventional four-transistor (4T) pixel cell;

FIG. 1B is a cross-sectional view of the conventional four-transistor pixel cell of FIG. 1A, taken along line A-A′;

FIG. 2A is a top-down view of the exemplary photocell constructed in accordance with a first exemplary embodiment of the invention;

FIG. 2B is a cross-sectional view of the exemplary photocell constructed in accordance with a first exemplary embodiment of the invention shown in FIG. 2A, taken along line A-A′;

FIG. 2C is a cross-sectional view of formed BJC with assignment of terminals shown;

FIG. 3A is a schematic diagram of the proposed photosensitive structure describing global biosing scheme for the first exemplary embodiment of the invention;

FIG. 3B is a schematic diagram of the proposed photosensitive structure describing biosing scheme with BJT operation with the floating emitter;

FIG. 3C is a schematic diagram of the proposed photosensitive structure describing biosing scheme for the BJT operation with the floating emitter without global bios voltage;

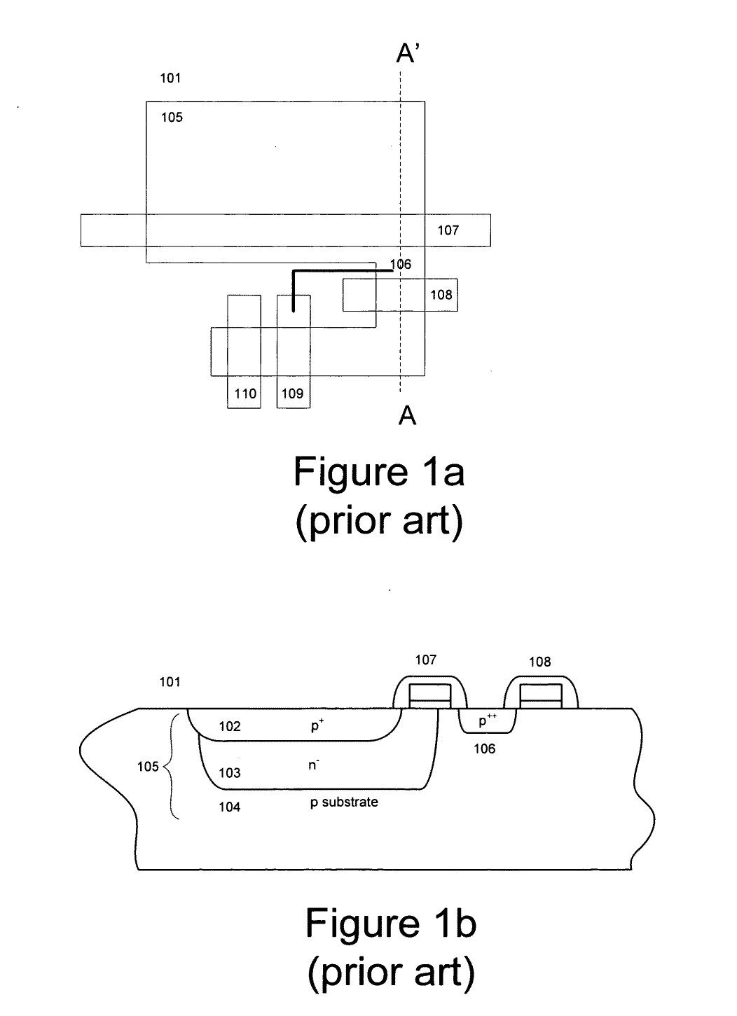

### DETAILED DESCRIPTION OF THE INVENTION

Although the invention described herein with reference to the architecture and fabrication of one pixel cell, it should be understood that this is representative of a plurality of pixel cells in an array of an imager device. In addition, the invention has applicability to many solid state imaging devices having pixel cells, and is not limited to the configuration described herein. The following detailed description is, therefore, not to be taken in a limiting sense, and the scope of the invention is defined only by the appended claims.

The term “pixel” refers to a picture element unit cell containing a photo sensor and transistors for converting light radiation to an electrical signal. For purposes of illustration, a representative pixel is illustrated in the figures and description herein and, typically, fabrication of all pixels in an imager will proceed simultaneously in a similar fashion.

The term “substrate” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “substrate” in the following description, previous process steps may have been utilized to form regions or junctions in the base semiconductor structure or foundation. In addition, the semiconductor need not be silicon-based, but could be based on silicon-germanium, germanium, or gallium arsenide.

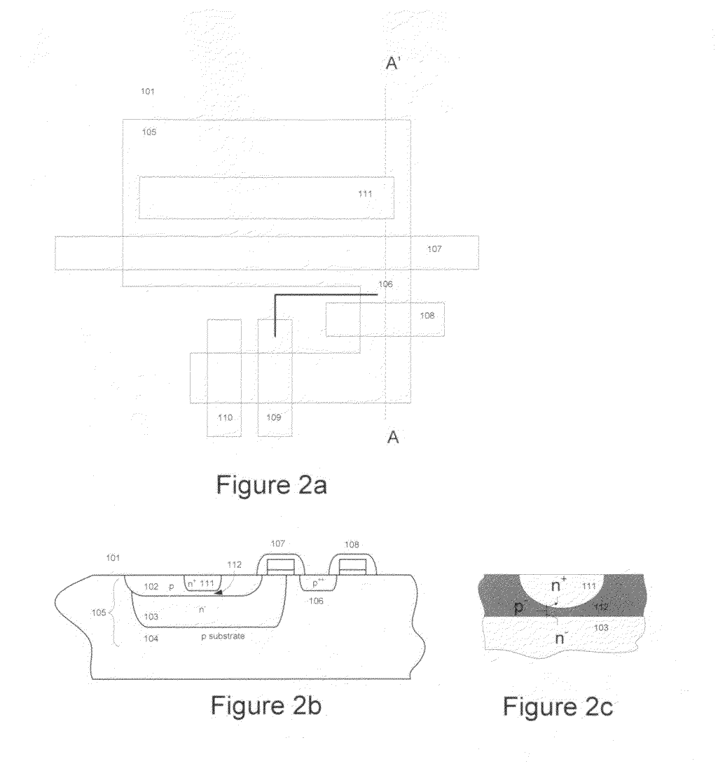

With the addition of an extra n+ doped layer at the surface the n-p-n BJT is formed with its emitter in the n+ region 111, base in the p region 112 and collector in the region 103. It should be understood that more than one n+ region can be formed creating as many BJTs and that the size and the precise geometry of the n+ layer can be different from shown in FIG. 2a. It possible for example to make n+ region in such a way that it covers photodiode completely in order to maximize the size of the BJT. It is also possible to form an emitter region 111 outside the active area of the photodiode to avoid shading that can result from contact made to the emitter region.

The process of the light registration by the photodiode 100 consist of photon absorption, in which electron-hole pair is generated, and than separation of that pair by electric field existing in vicinity of the p-n junctions between the accumulation region 103 and the pinned layer 102 and the accumulation region 102 and p substrate 104. Electrons from those pairs will be pulled into the accumulation region 103 of the photodiode where they can be stored during accumulation step and later transferred to the floating diffusion 106 by means of the transfer gate 107. Holes that were generated in the process of light adsorption migrate into p doped layers 102, 112 and 104.

The photo-generated holes that are pulled into the p layer 112 represent BJT base current. This current will case an emission of the electrons from the emitter 111 in amount proportional to the number of holes. The ratio of the electrons emitted by the emitter to the number of holes entered the base region is equal to the BJT current gain β and usually vary from 10s to 100s in the current technology. These electrons will be pulled into the collector region 103 similar to those produced directly by the photon adsorption and thus will produce signal during readout phase. Therefore, an addition of the BJT described in this invention not only allows for the hole current to be registered but also to be amplified.

Electrons accumulated in the region 103 can be transferred to the floating diffusion 106 through TX gate 107 during the readout step and converted into voltage by the pixel source follower 109. During the transfer process accumulation/collector region 103 is fully depleted and is reset to its intrinsic value (or pinned potential).

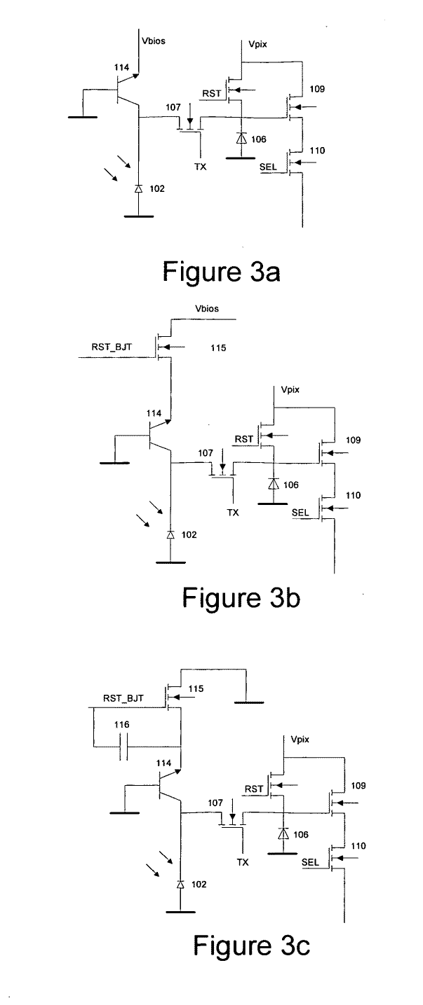

In order for BJT to operate efficiently proper bios to its emitter should be applied. Applicably to the exemplary embodiment where base region 112 is connected to the ground/substrate through the p region 102 emitter region 111 of the pixel can be connected to the global (common for all the pixels in the array) source of the bias voltage as shown in FIG. 3a.

This bios voltage can be used to control operation of the BJT 114 as shown in FIG. 3a. Making bios voltage more positive will move BJT into cutoff mode thus reducing its gain and eliminating its effect on the pixel operation. To maximize the BJT current gain bios voltage should be set slightly below base potential making sure however that BJT is still closed to minimize photodiode dark current.

FIG. 3b shows another possible way of providing bios to the BJT transistor. In this mode emitter of the BJT 114 is only connected to the bios voltage during the pixel reset and is floating during the accumulation phase. MOSFET switch 115 can connect/disconnect emitter of the BJT 114 to the global (common for the array) BIAS precharging the emitter region 114 to the bios voltage. Upon the completion of the reset step switch 115 is closed leaving the region 114 floating. Since during this precharge procedure charge injection into accumulation region 103 (FIG. 2b) can occur it is necessary to momentarily open the TX gate 107 to reset 103. When switch 115 is closed for the accumulation step BJT emitter 111 is disconnected from the bios voltage and its potential can change due to photo current induced migration of the electrons from the floating emitter 114 towards collector and photodiode accumulation region 103. Capacitance of the emitter region 111 that determines how much charge can be stored in the emitter region 111 can be controlled by its level of doping, geometry or by addition of dedicated capacitor from emitter to the substrate.

The aforementioned change in the emitter potential may be desirable effect since it will reduce emitter efficiency and can be utilized to make a pixel gain to decrease with charge accumulation. This effect can, for instance, be used for the pixel operation in the high-dynamic mode where it is desirable to decrease pixel gain based on the accumulated amount of photo-charge.

This change in the potential is also proportional to the photo signal and can be used to nondestructively (without performing readout) assess amount of charge accumulated inside the pixel by constantly or periodically monitoring the potential of the emitter region 111.

FIG. 3c shows a bios option similar to the mode described in [0020] but it does not need the global bios source. In this mode either external or intrinsic gate-source capacitance of the switch 115 denoted as 116 is used to provide a negative charge injection into emitter region 111 of the BJT 114. Charge injection will occur when a MOSFET switch 115 is closed and its gate is still driven to a lower potential. In this method it is possible to precharge emitter region 114 to negative potential in the respect to substrate 104 (FIG. 2b). The amount of charge injection in this method can be controlled by amplitude of the voltage swing applied to the gate of the MOSFET switch 115.

It should also be mentioned that it is possible to manufacture BJTs to make the base float. Applicably to the described embodiment this could be achieved by allowing n-region of the photodiode to extend to the surface on the perimeter of the photodiode. This will electrically isolate pinned layer 102 along with a BJT base region 112 from the substrate 104 (all per FIG. 2b) and make it floating. Emitter region of the BJT 111 should be connected to the source of the negative voltage (in respect to substrate). This voltage can be global for the array.

Other embodiments of a pixel cell 100 (FIG. 2a) may be constructed in accordance with the invention. For example, although the exemplary pixels 100, have been described as having a p-type substrate 104, n-type accumulation region 103, and p-type pinned 102 and BJT base 112 regions, and n+ type emitter region 111, the invention is not limited to the described configuration. It should be understood that other configurations, including a pixel cell having a reversed doping profile, are other embodiments that are within the scope of the present invention.

What is claimed as new and desired to be protected by Letters Patent of the United States is:

1. A method of forming a photo detector comprising steps of:
forming a photosensitive structure with one or more BJT having base emitter and burred collector region;
forming photosensitive structure with a pinned photodiode and one or more BJT where photodiode accumulation region coincide with the BJT collector region;
forming a photosensitive structure where BJT converts current of the photo generated carriers of the type that cannot be accumulated into complimentary type carriers that can be accumulated and later converted into readable signal.

2. A photo detector of the claim l where photosensitivity at least partially comes from the BJT operation.

3. A photo detector of the claim 1 where BJT(s) is formed with burred n region as a collector, a base is formed in the p region adjacent to the collector and an emitter is formed in the n+ region adjacent to the base such that the emitter and the collector regions are separated by the base p region.

4. A photo detector of the claim 1 where BJT acts as an amplifier of photo generated charges providing a gain factor during conversion of one type of carriers into complimentary type carriers.

5. A photo detector of the claim 1 where base of the BJT is not tied to the voltage bias and emitter is connected to the bios voltage.

6. A photo detector of the claim 1 where base of the BJT is connected to the substrate and emitter is continuously tied to bios voltage.

7. A photo detector of the claim 1 where base of the BJT is connected to the substrate and emitter is periodically, during reset, is tied to the bios voltage via switch, usually MOSFEET, and is floating during the photo charge accumulation step.

8. A modification to the method of claim 7, wherein substrate potential is used as biasing voltage and a charge injection trough the gate capacitance of the MOSFET switch is used to set a potential of the BJT emitter at the end of the reset step.

9. A mode of operation of the photo detector from claim 1, 7, and 8 in which potential of the floating BJT emitter is constantly monitored during charge accumulation indirectly providing the amount of accumulated photo charge without destructive readout or the photocell.

10. A mode of operation of the photo detector claim 1, 7, and 8 where a potential change of the floating BJT emitter occurring during charge accumulation is used to reduce pixel sensitivity to produce a pixel with larger dynamic range.

11. Photocell comprising of photosensitive structure from claim 1, charge transfer transistor, sensing node, reset transistor, source follower and row-select transistor.

12. A focal plane array comprising of plurality of pixels at least one of which utilizes a photosensitive structure specified in claim 1.

13. A photo sensor from claim 1 where reverse doping profile is used meaning that p regions become n and visa versa.
